(19) United States
(12) Patent Application Publication
(10) Pub. No.: US 2023/0397332 A1
(43) Pub. Date: Dec. 7, 2023

(54) METHOD FOR PRODUCING A CIRCUIT BOARD AND A SHAPED PART FOR USE IN THIS METHOD

(71) Applicant: JUMATECH GMBH, Eckental (DE)

(72) Inventor: Philipp WÖLFEL, Eckental (DE)

(21) Appl. No.: 18/027,590

(22) PCT Filed: Sep. 13, 2021
(86) PCT No.: PCT/EP2021/075095

§ 371 Date: Mar. 21, 2023

(30) Foreign Application Priority Data
Sep. 25, 2020 (DE) 10 2020 125 140.8

(51) Int. Cl. H05K 1/05; H05K 3/04; H05K 1/14; H05K 1/02

(52) U.S. Cl. CPC H05K 1/05; H05K 3/043; H05K 1/147; H05K 1/028; H05K 2203/0307; H05K 2201/05

(57) ABSTRACT

A method for producing a circuit board and a shaped part for use in this method are provided. To simplify the production of circuit boards, save insulating material and thereby also reduce the height of the circuit board for efficient heat management, the method according to the invention for producing circuit boards comprises the following steps: Step A: providing an electrically conducting shaped part (1) with at least two segments (2a-g), which are integrally connected just by webs of material (M); Step B: embedding the segments (2a-g) in insulating material to form at least one circuit-board substrate (LS); Step C: applying a conductor structure (4a, 4b) to the circuit-board substrate (LS) to form the circuit board (LP); and Step D: releasing the integral connection of the segments (2a-g) by breaking through the webs of material (M).

### CROSS REFERENCE TO RELATED APPLICATIONS

This application is a U.S. National Phase application under 35 U.S.C. 371 of International Application No. PCT/EP2021/075095, filed on Sep. 13, 2021, which claims priority to German Patent Application No. 10 2020 125 140.8, filed on Sep. 25, 2020. The entire disclosures of the above applications are expressly incorporated by reference herein.

### BACKGROUND

### Technical Field

The present invention relates to a method for producing a circuit board and to a shaped part for use in this method.

### Related Art

In the production of circuit boards, especially for high-current applications, current-carrying components are embedded in insulating material as conductors or conductor elements and connected to conductor structures for connecting electronic components to the circuit board. Corresponding circuit boards and production methods are known from EP 1 842 402 and DE 10 2011 102 484.

In the known production methods, the conductors or conductor elements are positioned on a copper foil and welded to it, then pressed with insulating material before a conductor structure with strip conductors and connection points is worked out of the copper foil.

Based on the above-mentioned prior art, the problem underlying the present invention is to simplify the production of circuit boards, in particular with a plurality of segments, to save insulating material and thereby also to reduce the height of the circuit board, among other things, in order to make heat management on circuit boards significantly more efficient.

The problem of the invention is solved by a new method and a new shaped part.

### SUMMARY

The method for producing circuit boards according to the invention comprising the following steps:
Step A: Providing an electrically conducting shaped part with at least two segments which are integrally connected (along a joint) by webs of material.
Step B: Embedding the segments in insulating material to form at least one circuit-board substrate.
Step C: Applying a conductor structure to the circuit-board substrate to form the circuit board.
Step D: Releasing the integral connection of the segments by cutting through the webs of material.

In order to form the segments and, if necessary, different circuit board sections, slot-shaped perforations are introduced into the shaped part along a perforation line, for example. The segments correspond, for example, to the conductors according to patent application EP 1 842 402 and/or the shaped parts according to patent application DE 10 2011 102 484, the contents of which are included by reference herein. Basically, little material is intended to be removed during formation of the segments, since with increasing segmentation, the required processing time possibly also increases. The segmentation of the shaped part is intended to create a joint which is preferably completely filled with insulating material in the final state of the circuit board. However, it has proved advantageous to separate the individual segments from one another only after the conductor structure has been attached, because this considerably simplifies the positioning of the conductor structure in relation to the segments. The joint between the segments should be at least as wide as to prevent electrical breakdown through the joint by the insulating material to be applied. In this context, a minimum width of approx. 200 μm has proved to be preferred. However, the joint should not be too wide either, because the removed material has to be filled with insulating material when the shaped part is embedded in insulating material. Since insulating material is preferably applied laminarly, e.g. as an insulating mat (pre-preg=resin-impregnated fiber mat), there is a lack of corresponding insulating material at the joint. With a correspondingly small joint, the material deficit can be easily compensated. In the case of a larger joint, groove-like depressions could possibly form along the joint on the surface of the circuit board and lead to delamination, which is to be avoided as far as possible. A maximum width of the perforation line or joint of approx. 2000 μm seems reasonable. The intermediate product after embedding the shaped part in insulating material is referred to in the scope of the present invention as a circuit-board substrate. A conductor structure for connecting electronic components is then attached to this circuit-board substrate. For this purpose, the circuit-board substrate is coated with a copper foil, for example, from which strip conductors and connection points are subsequently worked out, e.g. using an etching process. However, prefabricated conductors and pads can also be attached to the circuit-board substrate as a conductor structure. According to the invention, the integral connection of the segments is released after attachment of the conductor structure by cutting through the webs of material. This allows the conductor structure to be positioned particularly accurately in relation to the embedded segments. By embedding in the insulating material, the positions of the segments relative to each other are fixed and remain aligned even after cutting through the webs of material. The phrase “webs of material” in the plural is also intended to include a single web of material in the singular.

As a result, the invention also favors minimization of the amount of insulating material used in the production of the circuit board, which yields several advantages at once: On the one hand, material costs are saved and, on the other hand, the thickness or overall height of the circuit board is reduced. The less insulating material used, the thinner the circuit board. The thinner the joint, the less insulating material (or resin) is required to fill the joint. In addition, the insulating material is not only electrically insulating, but also heat insulating, so that reducing the amount of insulating material also favors the heat management of the circuit board.

It is within the scope of the invention that steps A to D are preferably, but not mandatorily, carried out in the sequence indicated. As indicated below, the steps and sub-steps of the method can also be carried out, at least partially, in a modified order.

Preferred further embodiments of the invention are the subject matter of the dependent claims.

It may be reasonable if step A comprises at least one of the following sub-steps, wherein the substeps are preferably, but not mandatorily, carried out in the indicated order
A-1: Providing the electrically conducting shaped part as a preferably planar surface element made of metal, preferably of copper, particularly preferably with a thickness in the range of 200 to 1000 μm.
A-2: Attaching or forming at least one reference mark on the shaped part. The reference mark can be, for example, a character, a symbol, a cross or an opening in the shaped part. It is significant that this reference mark is clearly defined. Ultimately, the reference mark serves to determine a coordinate system on the shaped part, so that positions on the shaped part can be unambiguously determined using the reference mark. This is particularly preferred for positioning the subsequent conductor structure in relation to the segments and for later cutting through the webs of material. After embedding the shaped part in insulating material, the joint or the web of material is usually covered with insulating material and not visible. Accordingly, the positions of the webs of material must be known exactly in order to be able to cut through them in a targeted manner. By means of the reference mark, the conductor structure of the circuit board can be defined or formed with positional accuracy, so that the webs of material, which must be accessible to the appropriate tool for later cutting through, are not covered by the conductor structure or made inaccessible in any other way. The reference mark is preferably machine-readable or optically recognizable with an optical device.
A-3: Aligning the shaped part (e.g. in relation to a press assembly) using at least one reference mark on the shaped part. This simplifies the processing of the shaped part in the subsequent processing steps.
A-4: Perforating the shaped part along at least one perforation line to form at least one circuit board section with the at least two segments, preferably as a function of at least one reference mark of the shaped part, preferably comprising at least one of the following substeps:
A-4-1: Forming a self-contained perforation line around the circuit board section so that the circuit board section within the perforation line is integrally connected to a surrounding edge region outside the perforation line only via isolated webs of material, wherein the self-contained perforation line preferably has a polygon shape. Along the self-contained perforation line, the circuit board section can be easily separated from the shaped part, preferably after completion of the circuit board. The polygonal shape facilitates the separation of the circuit board section from the surrounding material.
A-4-2: Forming at least one open (i.e. not closed) or closed perforation line for dividing the circuit board section into the segments, wherein this open or closed perforation line preferably starts and/or ends at an edge of the circuit board section, particularly preferably at a perforation line enclosing the circuit board section. With these perforation lines, any segments can be formed within the circuit board section. With a self-contained perforation line, it is also possible to form a circuit board segment within another circuit board segment.
A-4-3: Forming the at least one perforation line with a preferably uniform width, preferably a width in the range from 200 to 2000 μm, preferably such that slot-shaped perforations along the perforation line are spaced apart from one another by the webs of material. The perforation line forms the subsequent joint between the segments, which is ideally completely filled with insulating material in the finished state of the circuit board.
A-4-4: Perforating the shaped part by material removal, preferably by laser radiation or by etching, preferably such that more than 90%, 95% or 99% of the material of the shaped part is removed along the perforation line, wherein the remainder is left as webs of material. In an exemplary embodiment, the webs of material measured along the perforation line are, for example, about 500 μm or 0.5 mm wide. The distance between two webs of material along the perforation line is, for example, approx. 50 mm, i.e. one hundred times the width of the webs of material. In this example, approx. 99% of the material of the shaped part has been removed along the perforation line.
A-4-5: Forming a plurality of identical or different circuit board sections in the shaped part, preferably such that the circuit board sections are distributed in rows and columns across the shaped part in a matrix shape. This allows the area of the shaped part to be ideally utilized for forming the greatest possible number of circuit board sections.
A-5: Forming at least one opening in the shaped part, preferably in the region of at least one circuit board segment, preferably within a self-contained parting line. This allows nonconducting or insulating segments to be formed.
A-6: Filling the at least one opening of the shaped part with insulating material, preferably in such a way that the surface of the insulating material is flush with the surface of the shaped part. This measure facilitates the subsequent pressing of the shaped part with insulating material.
A-7: Roughening of the shaped part, preferably by chemical or mechanical processing. This allows the subsequent connection between the insulating material and the shaped part to be improved. Corresponding techniques are disclosed in the application DE 10 2012 216 926, the contents of which are included by reference herein.

It may be useful if step B comprises at least one of the following sub-steps, wherein the sub-steps are preferably, but not mandatorily, carried out in the indicated order:
B-1: Providing the insulating material in a moldable state, preferably as a flexible surface element, preferably as a pre-preg (resin-impregnated fiber mat), particularly preferably with a size matched to the shaped part. An insulating mat can have a corresponding reference mark which is applied with the reference mark of the shaped part, for example, for congruence. This ensures that the insulating mat is optimally positioned relative to the shaped part.
B-2: Applying the insulating material to one side or both sides of the shaped part, preferably such that the insulating material coats the respective side of the shaped part laminarly, preferably with uniform layer thickness. This technique allows the shaped part to be embedded in insulating material in a particularly simple manner.
B-3: Introducing the insulating material between the segments of the shaped part, preferably by pressing the insulating material onto the shaped part, preferably in such a way that the insulating material partially or completely fills the space between the (web of material and/or) segments, particularly preferably in such a way that insulating material layers arranged on both sides of the shaped part are integrally connected by the insulating material. This already ensures extensive electrical insulation of the segments along the joint while minimizing the risk of electrical breakdown and avoiding air pockets in the joint.
B-4: Embedding each segment in insulating material so that the segment is completely surrounded by insulating material on all sides with the exception of the webs of material. This defines the positions and orientations of the segments relative to each other, which in particular facilitates the precise attachment of a conductor structure relative to the segments. Ideally, each circuit board section is also embedded in insulating material so that the circuit board section is completely surrounded on all sides by insulating material, with the exception of the webs of material. This defines positions and orientations of multiple circuit board sections with respect to each other, which facilitates subsequent processing in the production of a plurality of circuit boards from a shaped part.
B-5: Curing of the insulating material. In this way, all circuit board sections and segments are permanently fixed in their position and orientation relative to each other, wherein these relative positions and orientations of the segments are maintained even after the web of material has been cut through and the circuit board has been released from the circuit-board substrate.

It may prove expedient if step C comprises at least one of the following sub-steps, wherein the sub-steps are preferably, but not mandatorily, carried out in the indicated order
C-1: Providing an electrically conducting surface element, preferably of metal, preferably of copper, particularly preferably as a foil, very particularly preferably with a size matched to the shaped part. For example, the copper foil has a thickness in the range from 15 μm to 110 μm.
C-2: Applying an electrically conducting surface element to one side or to both sides of the circuit-board substrate, preferably such that the electrically conducting surface element coats the respective side of the circuit-board substrate laminarly, preferably with uniform layer thickness. This step can already be carried out in connection with step C, e.g. during step C3.
C-3: Positioning the conductor structure, which preferably has strip conductors and/or connection points, on the circuit-board substrate as a function of at least one reference mark of the shaped part, preferably such that the conductor structure, when projected onto the plane of extension of the shaped part, is arranged offset from the webs of material and does not cover the webs of material. The phrase “strip conductors” and/or “connection points” and/or “webs of material” in the plural is also intended to include a single strip conductor, connection point or web of material. Strip conductors and connection points do not necessarily have to be etched out of a copper foil. It is also possible to apply strip conductors and connection points from prefabricated components onto the circuit-board substrate. The positioning of these components is facilitated by the reference mark.
C-4: Working out the conductor structure, which preferably has strip conductors and/or connection points for electronic components, from the electrically conducting surface element, preferably by material removal, preferably by etching. Here, too, the positions of the strip conductors and/or connection points are preferably defined in relation to the reference mark.
C-5: Connecting the conductor structure to at least one circuit board segment, preferably by means of contacts, preferably by means of through-connecting. A connector to be inserted later can also ensure the connection to the circuit board segment without a connection to a conductor structure.

It may be advantageous if step D comprises at least one of the following sub-steps, wherein the sub-steps are preferably, but not mandatorily, carried out in the indicated order
D-1: Providing a tool for cutting through the webs of material.
D-2: Aligning the tool for cutting through the webs of material to the circuit board as a function of at least one reference mark on the shaped part. If, for example, the webs of material are covered by insulating material, the positions of the webs of material are not visible to the naked eye, but must be determined otherwise. The position of the web of material can be determined precisely by means of the reference mark. By reading in the reference mark and passing on the information to a tool controller, the tool can be guided precisely to the position of a web of material to be cut through in order to release the integral connection between the segments in a targeted manner.
D-3: Cutting through the webs of material by material removal, preferably by drilling or milling, preferably perpendicular to the extension plane of the shaped part. Ideally, the entire web of material is removed during cutting, so that the risk of electrical breakdown at the location of the previous web of material is minimized. In this process, two slot-shaped perforations (filled with insulating material), which were previously separated by the web of material, are analogously connected to form a continuous joint.
D-4: Filling the separation points of the webs of material with insulating material, preferably such that a joint between the segments is completely filled with insulating material. This minimizes the risk of electrical breakdown between segments across the joint.

According to this method, a circuit board consisting of several planes can also be produced. Two or more shaped parts can also be present in such a circuit board, or two or more circuit boards can be connected by a shaped part to form a, in particular, three-dimensional circuit board arrangement. The shaped parts can be arranged parallel to each other. The conductor structure can also extend over several planes.

Another aspect of the present invention relates to a shaped part for producing a circuit board, preferably according to the method according to one of the preceding embodiments, comprising two segments which are integrally connected only via isolated webs of material. This shaped part can be prefabricated as a mass-produced component and provided for the production of a plurality of circuit boards in series production.

It can be useful if the shaped part has slot-shaped perforations along a perforation line, which are interrupted by the webs of material.

Another aspect of the present invention relates to a circuit board arrangement comprising at least two circuit boards and at least one shaped part according to one of the two preceding embodiments, wherein each segment of the shaped part is connected to the at least two circuit boards and the segments of the shaped part are electrically insulated from each other by cutting through the webs of material. This allows articulated or angled as well as electrically conducting connections between the circuit boards to be created by the segments in a particularly simple manner.

Further preferred embodiments of the invention result from any combination of the features disclosed in the description, claims and drawings.

### Terms and Definitions

### Shaped Part

In the context of the present invention, the term “shaped part” is preferably understood to mean a laminar, plate-shaped component, in particular made of an electrically conducting solid material such as metal, in particular copper. The shaped part preferably has no irregularities or interruptions within its contour.

### Perforating

During perforating, slots or holes are made in the shaped part along the perforation line where the segments can be easily cut off.

### Conductor Structure

The term “conductor structure” is understood to mean anything capable of effecting an electrically conducting connection to at least one of the segments through the insulating material. The conductor structure preferably has at least one of the following elements: strip conductor, connection point, pad, conductor, contact, via, through-contact. The conductor structure is preferably an arrangement comprising several of these elements, possibly several different ones of these elements.

### Electronic Component

In the context of the present invention, an electronic component is understood to be, for example, a current-generating or current-consuming component, such as a processor, memory, transistor, resistor, generator, a diode, in particular an LED; or a component associated therewith, such as for example an optical component, for example a lens; but also a connection component, such as for example a plug, terminal or the like.

Unless otherwise indicated, formulations in the plural are used in the context of the invention for practical reasons in order to avoid linguistically more complex differentiations according to singular and plural. It is within the scope of the invention that formulations in the plural (e.g. “webs of material”) include both the singular (“one web of material”) and the plural (“several webs of material”).

### BRIEF DESCRIPTION OF THE DRAWINGS

FIG. 1 is a schematic view of a shaped part according to a first embodiment in top view for use in a method according to the invention, wherein the shaped part has a circuit board section with two segments which are integrally connected along a perforation line only via isolated webs of material.

FIG. 2 is a schematic exploded view of the components of a circuit-board substrate for the production of a circuit board according to the method of the invention, wherein both on the upper side and on the lower side of the shaped part according to FIG. 1 in each case first an electrically insulating layer and then an electrically conducting layer are arranged in order to form the circuit-board substrate in the layer composite.

FIG. 3 is a schematic side view of a circuit-board substrate formed from the components shown in FIG. 2, with electrically conducting layers on the upper and lower sides.

FIG. 4 is a schematic side view of a circuit board formed from the circuit-board substrate according to FIG. 3 after forming upper- and lower-sided conductor structures and connecting them to the segments.

FIG. 5 is a schematic top view of a shaped part according to the second embodiment, wherein a total of four virtually identical circuit board sections with a polygonal contour, each with a plurality of segments, are arranged in the form of a matrix in two rows and two columns distributed over the shaped part, wherein the respective segments are integrally connected along perforation lines only via isolated webs of material, wherein the subsequent conductor structures are drawn in as dashed lines.

FIG. 6 is a schematic top view of a circuit board according to the invention, which is produced using the shaped part according to FIG. 5, wherein a conductor structure is formed on the circuit board and the integral connection of the segments is released after cutting through the webs of material.

FIG. 7(a) is a schematic top view of a blank for a shaped part according to the third embodiment, and FIG. 7(b) is a top view of the shaped part produced therefrom with several segments integrally connected via isolated webs of material.

FIG. 8 is a schematic top view of an arrangement with several circuit-board substrates connected via shaped parts according to FIG. 7.

FIG. 9 is a schematic top view of the arrangement shown in FIG. 8, wherein the circuit-board substrates are provided with conductor structures.

FIG. 10 is a schematic top view of the arrangement shown in FIG. 9, wherein the webs of material between the segments are cut through to electrically insulate the segments.

### DETAILED DESCRIPTION

The preferred embodiments of the invention are described in detail below with reference to the accompanying drawings.

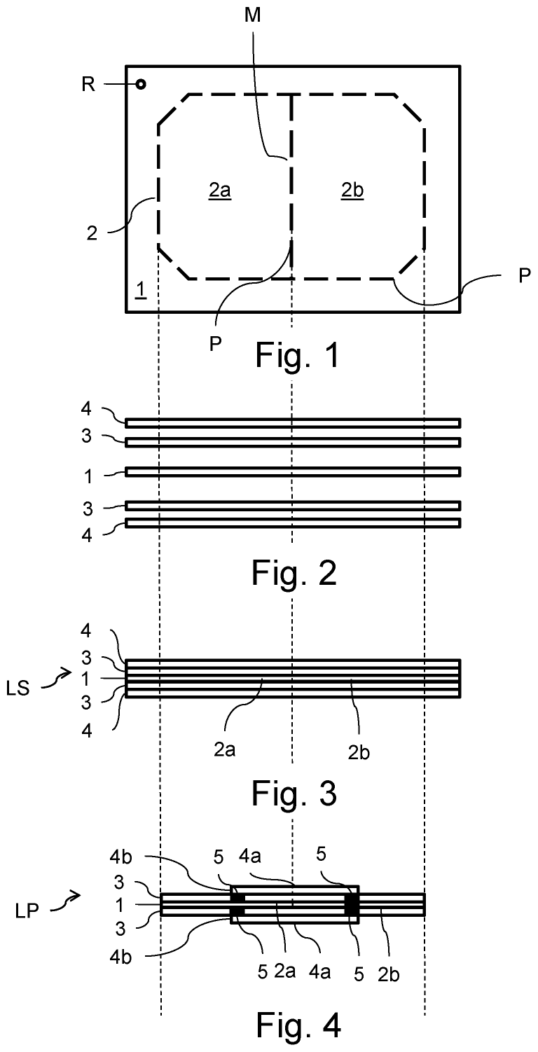

### First Embodiment (FIGS. 1-4)

In the first embodiment of the invention, which is described below with reference to FIGS. 1-4, a circuit board LP is manufactured in layered construction starting from an electrically conducting shaped part 1 in the form of a rectangular copper plate having a thickness in the range of, for example, 200-1000 μm.

In step A of the method according to the invention, the shaped part 1 is provided for subsequent processing. In this process, two segments 2a, 2b of a circuit board section 2 are formed by introducing corresponding perforation lines P into the shaped part 1. In the present embodiment, the circuit board section 2 is formed within a self-contained, polygonal perforation line P with eight corners. During perforating, long, slot-shaped openings with a preferably constant width in the range from approx. 200 to 2000 μm are introduced into the shaped part 1 along the perforation line P by appropriate material removal, so that the segments 2a, 2b remain integrally connected only by means of isolated webs of material M. The entire circuit board section 2 is connected via the self-contained perforation line P to the surrounding edge region of the shaped part 1, in which a reference mark R is located. The reference mark R is used to determine the position on the surface of the shaped part 1 and is, for example, an opening with which the shaped part 1 is placed on a pin. Several reference marks R can be provided on the shaped part 1.

After forming the segments 2a, 2b, the shaped part 1 is embedded at least in sections in insulating material 3 in step B of the method according to the invention. The resulting intermediate product is referred to as circuit-board substrate LS. Two resin-impregnated fiber mats (pre-preg) 3, ideally of a shape and size matched to the shaped part 1, are applied to the upper and lower sides of the shaped part 1. These resin-impregnated fiber mats 3 are pressed together with the shaped part 1 in such a way that the flowable resin penetrates into the perforations along the perforation line P and completely permeates the spaces between the webs of material M. In this step, also the electrically conducting surface element 4, from which the conductor structure is worked out in step C, can simultaneously be connected to the insulating material by pressing. In this process, for example, a sandwich-like layer composite, as shown in FIG. 3, consisting of the shaped part 1, two insulating mats 3 and two copper foils 4, is jointly pressed. By curing the insulating material 3, the positions and orientations of the segments 2a, 2b relative to each other are fixed so that they are maintained later—even after the web of material M has been cut through.

In step C of the method according to the invention, the conductor structure 4a, 4b is attached to the circuit-board substrate LS. This step comprises as a sub-step applying at least one copper foil 4 as an electrically conducting surface element to the circuit-board substrate LS, for example one copper foil 4 each on both the upper side and the lower side of the circuit-board substrate LS. This is preferably already done in step B, so that the copper foils 4 are pressed together with the shaped part 1 and the insulating material 3 arranged in each case between the copper foil 4 and the shaped part 1 to form a layer or material composite. In step D, a conductor structure with strip conductors 4a and connection points 4b is then formed from this copper foil 4, e.g. using an etching process. At the connection points 4b, the strip conductors 4a are connected to the segments 2a, 2b via contacts 5 (e.g. vias or laser vias (left) or through-contacts (right)).

After forming the conductor structure 4a, 4b on the circuit-board substrate LS, the webs of material M, which integrally connect the segments 2a, 2b, are cut through by material removal. This is accomplished, for example, with a drill that is guided to the corresponding positions of the webs of material M by means of the reference mark R. When cutting through the webs of material M, preferably all the material of the webs of material M is removed over the entire length corresponding to the width of the former perforation line P, which now forms a joint. If necessary, the separation point is filled with insulating material 3 so that the risk of electrical breakdown between the segments 2a, 2b—especially at the points of the former webs of material M—is minimized. Whether or not the separation point is filled with insulating material 3 can be determined primarily as a function of the dielectric strength of the circuit board or the insulating material.

Subsequently, the finished circuit board LP is separated from the surrounding region along the self-contained perforation line P, which surrounds the circuit board section 2 and the segments 2a, 2b.

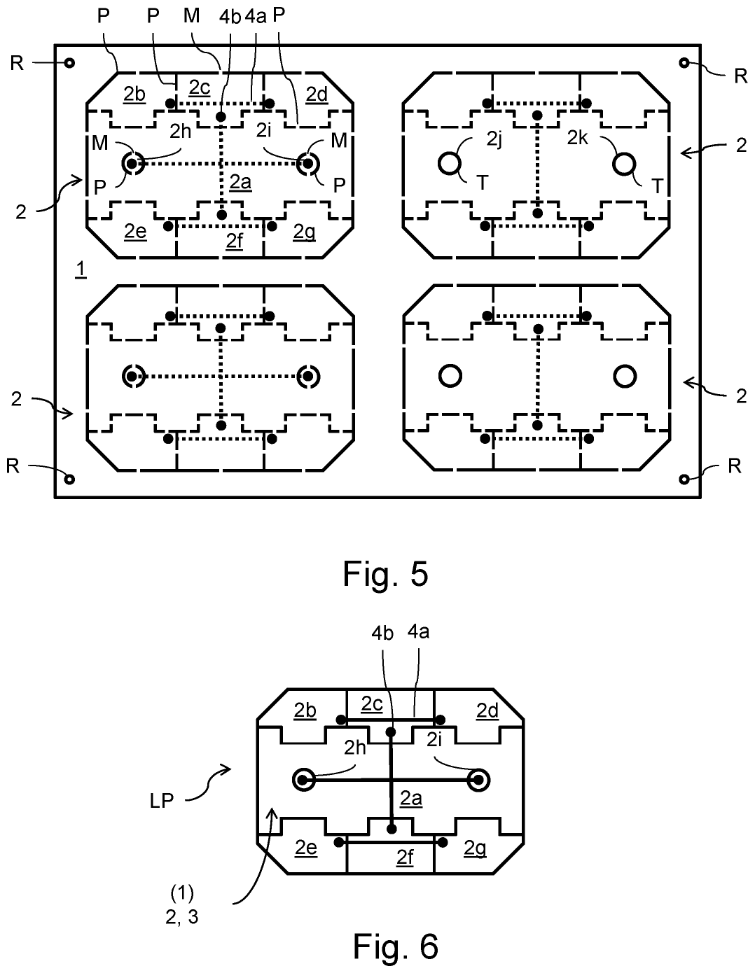

### Second Embodiment (FIGS. 5 and 6)

The second embodiment of the present invention, which is described below with reference to FIGS. 5 and 6, is based substantially on the first embodiment. Identical features are indicated by identical reference signs, wherein the relevant differences are explained below.

In the second embodiment, the shaped part 1, which is configured as a rectangular copper plate, comprises a total of four largely identical circuit board sections 2, which are arranged in matrix form in two columns and two rows distributed over the surface of the shaped part 1.

An octagonal, self-contained perforation line P surrounds each of the four circuit board sections 2. Each circuit board section 2 within the circumferential perforation line P is integrally connected to a surrounding edge region of the shaped part 1, on which various reference markings R are located, by means of the isolated webs of material M. Within each circuit board section 2, a plurality of segments 2a-i are formed by further perforation lines P. For illustration purposes, the subsequent conductor structure 4a, 4b with connection points 4b and strip conductors 4a extending between them is drawn by dash lines in each circuit board section 2. It can be seen here that the conductor structure 4a, 4b does not cover the webs of material M when projected onto the extension plane of the shaped part 1. Consequently, the webs of material M are accessible for later processing.

Preferably, the segments 2a-i and perforation lines P completely fill the respective circuit board section 2 surface-wise, as shown in the two circuit board sections 2 in the left half of FIG. 5. However, it is also possible that a circuit board section 2 or at least one circuit board segment 2a-i has at least one opening 2j, 2k, as shown in the two circuit board sections 2 in the right half of FIG. 5.

Deviating from the two circuit board sections 2 in the left half of FIG. 5, the two circuit board sections 2 in the right half of FIG. 5 have two openings 2j, 2k in the circuit board segment 2a instead of the segments 2h, 2i. The material of the shaped part 1 corresponding to the regions of the openings 2j, 2k is thereby completely separated and removed from the shaped part 1 in step B along a self-contained parting line T in each case. In step C or before, a preferably cured insulating material 3 is introduced into each opening 2j, 2k to ideally completely fill the openings 2j, 2k and to later form an electrically non-conducting circuit board segment. Filling the openings 2j, 2k with cured insulating material 3 is useful because, when the shaped part 1 is subsequently pressed with insulating material in the form of resin-impregnated fiber mats (pre-preg), the free resin of the insulating material 3 is only available or flowable to a limited extent, and is mainly used to fill the perforations along the perforation line P. An almost equal height of the insulating material plates introduced into the openings 2j, 2k with respect to the height of the shaped part 1 is preferred, so that the upper and lower sides of the insulating material 3 are flush with the upper and lower sides of the shaped part 1.

As in the first embodiment, this shaped part 1 (still without the conductor structure drawn in for illustration purposes only) is embedded in insulating material 3 and then provided with a corresponding conductor structure 4a, 4b at the positions shown in FIG. 5. After forming the conductor structure 4a, 4b, the webs of material M are cut along the perforation lines P and the resulting drill holes are filled with insulating material 3 if necessary. Finally, each circuit board LP is separated from the material composite along the outer perforation line P surrounding the circuit board section 2.

The number and shapes of PCB sections 2 and segments 2a-i as well as reference marks R can be changed as desired.

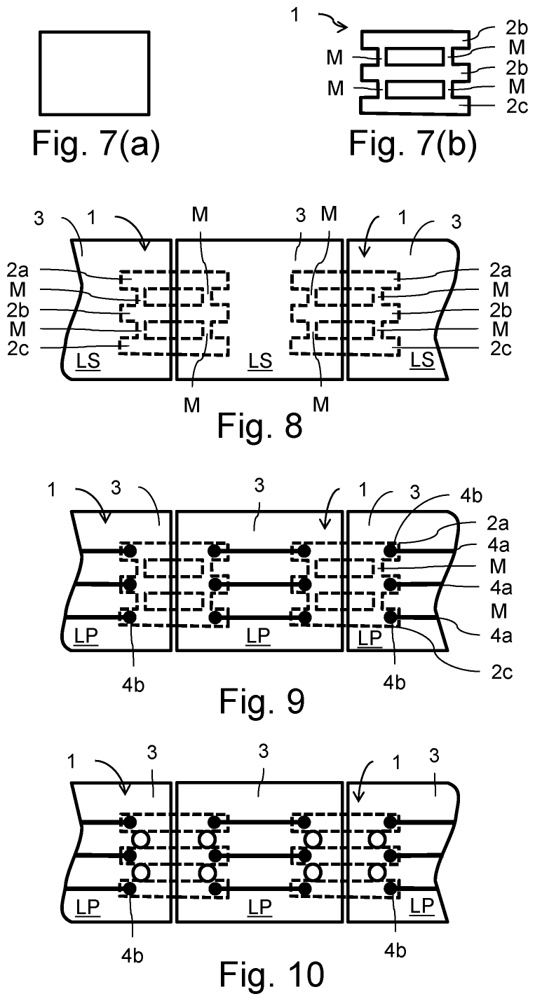

### Third Embodiment (FIGS. 7 to 10)

The third embodiment of the present invention, which is described below with reference to FIGS. 7 to 10, is based substantially on the first and second embodiments. Identical features are indicated by identical reference signs, wherein the relevant differences are explained below.

Here, the shaped part 1 is used to produce three-dimensional circuit board structures and, in particular, to form articulated or angled connections between two or more circuit boards LP. Deviating from the preceding embodiments, each segment 2a, 2b, 2c is connected to two circuit-board substrates LS or circuit boards LP, so that the respective segment 2a, 2b, 2c forms an articulated or angled connection between two or more circuit boards LP or circuit-board substrates LS.

The shaped part here is an approximately conductor-shaped element which is worked out of a planar, rectangular copper plate (FIG. 7a) in step A of the method according to the invention. The horizontally extending sections in FIG. 7b correspond to segments 2a, 2b, 2c, the vertically extending sections which connect segments 2a, 2b, 2c correspond to the webs of material M.

In step B, the shaped part 1 is embedded in insulating material 3 to form circuit-board substrates LS. In this process, each segment 2a, 2b extends over almost half of its length in a first circuit-board substrate LS and over almost half of its length in a second circuit-board substrate LS.

In step C, conductor structures are created on one or more of these circuit-board substrates LS to form the circuit board LP. For this purpose, the shaped part 1 is connected to an electrically conducting surface element such as a copper foil, or via connecting means sections, as known from DE 10 2018 203 715. Subsequently, the strip conductors 4a as well as the connection points 4b for contacting the segments 2a, 2b, 2c are worked out of this electrically conducting surface element, e.g. by etching.

In step D, the web of material M is cut through so that the integral connections between the parallel segments 2a, 2b, 2c are released.

1-8. (canceled)

9. A method for manufacturing circuit boards, comprising:
step A: providing an electrically conducting shaped part with at least two segments which are integrally connected by webs of material;
step B: embedding the segments in insulating material to form at least one circuit-board substrate;
step C: applying a conductor structure to the circuit-board substrate to form the circuit board; and
step D: releasing the integral connection of the segments by cutting through the webs of material.

10. The method according to claim 9, wherein step A comprises at least one of the following sub-steps:
A-1: providing the electrically conducting shaped part as a planar surface element made of metal;
A-2: attaching or forming at least one reference mark on the shaped part;
A-3: aligning the shaped part using the at least one reference mark; and
A-4: perforating the shaped part along at least one perforation line to form at least one circuit board section with the at least two segments, as a function of the at least one reference mark of the shaped part;
A-5: forming at least one opening in the shaped part in the region of at least one of the segments, within a self-contained parting line;
A-6: filling the at least one opening of the shaped part with insulating material such that the surface of the insulating material is flush with the surface of the shaped part; and
A-7: roughening of the shaped part by chemical or mechanical processing.

11. The method according to claim 9, wherein step B comprises at least one of the following sub-steps:
B-1: providing the insulating material in a moldable state as a flexible surface element;
B-2: applying the insulating material to one side or both sides of the shaped part, such that the insulating material coats the respective side of the shaped part laminarly;
B-3: introducing the insulating material between the segments by pressing the insulating material onto the shaped part so that the insulating material partially or completely fills the space between the segments;
B-4: embedding each circuit board segment in insulating material so that the circuit board segment is completely surrounded by insulating material on all sides with the exception of the webs of material; and
B-5: curing of the insulating material.

12. The method according to claim 9, wherein step C comprises at least one of the following sub-steps:
C-1: providing an electrically conducting surface element;
C-2: applying an electrically conducting surface element to one side or to both sides of the circuit-board substrate such that the electrically conducting surface element coats the respective side of the circuit-board substrate laminarly;
C-3: positioning the conductor structure, with strip conductors and/or connection points, on the circuit-board substrate as a function of the at least one reference mark of the shaped part, such that the conductor structure, when projected onto the plane of extension of the shaped part is offset from the webs of material and does not cover the webs of material;
C-4: working out the conductor structure, with strip conductors and/or connection points for electronic components, from the electrically conducting surface element, by material removal; and
C-5: connecting the conductor structure to at least one circuit board segment by contacts.

13. The method according to claim 9, wherein step D comprises at least one of the following sub-steps:
D-1: providing a tool for cutting through the webs of material;
D-2: aligning the tool for cutting through the webs of material to the circuit board as a function of at the least one reference mark on the shaped part;
D-3: cutting through the webs of material by material removal by drilling or milling; and
D-4: filling the separation points of the webs of material with insulating material such that a joint between the segments is completely filled with insulating material.

14. A shaped part for producing a circuit board by the method according to claim 9, comprising at least two segments which are integrally connected via webs of material.

15. The shaped part according to claim 14, wherein the shaped part has slot-shaped perforations along a perforation line, which are interrupted by the webs of material.

16. A circuit board arrangement comprising:
at least two circuit boards; and
at least one shaped part according to claim 14,
wherein each segment of the shaped part is connected to the at least two circuit boards and the segments of the shaped part are electrically insulated from one another by cutting through the webs of material.

17. The method according to claim 10, wherein the electrically conducting shaped part is made of copper, and with a thickness in the range of 200 to 1000 μm.

18. The method according to claim 10, wherein the step A-4 comprises at least one of the following sub-steps:
A-4-1: forming a self-contained perforation line around the circuit board section so that the circuit board section within the perforation line is integrally connected to a surrounding edge region outside the perforation line only via isolated webs of material, wherein the self-contained perforation line has a polygon shape;
A-4-2: forming at least one open or closed perforation line for dividing the circuit board section into the segments, wherein the open or closed perforation line starts and/or ends at an edge of the circuit board section;
A-4-3: forming the at least one perforation line with a uniform width in a range from 200 to 2000 μm such that slot-shaped perforations along the perforation line are spaced apart from one another by the webs of material;
A-4-4: perforating the shaped part by material removal by laser radiation or by etching such that more than 90% of the material of the shaped part is removed along the perforation line, wherein the remainder is left as webs of material; and
A-4-5: forming a plurality of identical or different circuit board sections in the shaped part such that the circuit board sections are distributed in rows and columns across the shaped part in a matrix shape.

19. The method according to claim 11, wherein the flexible surface element is a resin-impregnated fiber mat with a size matched to the shaped part.

20. The method according to claim 11, wherein the insulating material layers arranged on both sides of the shaped part are integrally connected by the insulating material.

21. The method according to claim 12, wherein the electrically conducting surface element is copper.

22. The method according to claim 21, wherein the electrically conducting surface element is a foil.

23. The method according to claim 22, wherein the electrically conducting surface element has a size matched to the shaped part.
